(19) United States
(12) Patent Application Publication
(10) Pub. No.: US 2017/0287596 A1
(43) Pub. Date: Oct. 5, 2017

(54) PASSIVE INTERMODULATION TEST LEAD

(71) Applicant: HUBER+SUHNER AG, HERISAU (CH)

(72) Inventor: Maurizio DE CET, Schachen b. Herisau (CH)

(73) Assignee: HUBER+SUHNER AG, HERISAU (CH)

(21) Appl. No.: 15/512,462

(22) PCT Filed: Jul. 31, 2015
(86) PCT No.: PCT/EP2015/067691

§ 371 Date: Mar. 17, 2017

(30) Foreign Application Priority Data
Sep. 22, 2014 (CH) 01426/14

(51) Int. Cl. H01B 11/18; G01R 1/24; H02G 15/02; H01R 9/05; H02G 3/04

(52) U.S. Cl. CPC H01B 11/1869; H01R 9/05; H02G 3/0406; H02G 3/0481; H02G 15/025; G01R 1/24

(57) ABSTRACT

The invention is directed to a cable assembly (1) comprising a coaxial cable (2) with an inner conductor (3) and a shield (4) and a dielectric (5) arranged between the inner conductor (3) and the shield (4). The cable assembly (1) further comprises an outer jacket (7) which encompasses the coaxial cable (2). One or several spacers (10) are arranged between the coaxial cable (2) and the outer jacket (7) such that the outer jacket (7) and the coaxial cable (2) are spaced a distance apart.

### BACKGROUND OF THE INVENTION

### Field of the Invention

The present invention relates to a low PIM test cable according to the preamble of the independent patent claim.

### Discussion of Related Art

Coaxial test cables with very good passive intermodulation (PIM) performance are required when e.g. testing multicarrier wideband Radio Frequency (RF) systems. Such low PIM test cables (also called low PIM test leads) are during their lifecycle repeatedly flexed. The test cables should be extremely flexible with a low minimum bend radius. Furthermore the test cables should have a high resistance to resist kinking and over-bending and require a highly robust strain relief. Besides stable low PIM performance, low attenuation and good voltage standing wave ratio (VSWR) figures are important for coaxial test cables.

Known products are corrugated copper tube cable assemblies with or without armouring (Pasternack Enterprises, Times Microwave Systems, Kaelus), double braided RG-393 coax cable (RE-Light) and Conformable Semi-Rigid (tinned-braided cables) cable assemblies (Santron, RF Industries). The existing products are not easy to handle or do not offer a long product life. One major disadvantage is that they will degrade in performance after repeated use due to mechanical stress and damage. Double braided coax cables as such do not offer enough bending flexibility. Corrugated cables are also prone to kinking. Tinned-braided cables are susceptible to torque and also can break if the bend radius goes below the specified minimum.

EP1706877A1, first published in 2005 in the name of the same applicant, is directed to a coaxial cable that includes a central inner conductor, a dielectric that coaxially surrounds the inner conductor, a hand-shaped first outer conductor which is wound around the dielectric in a helical and overlapping manner, a woven high-tensile outer conductor that coaxially encloses the first outer conductor, and a sleeve which coaxially envelops the high-tensile outer conductor.

U.S. Pat. No. 5,061,823A was published 1991 on behalf of Gore Enterprise Holdings Ltd. and describes a crush, kink, and torque resistant, flexible coaxial cable having a closely spaced, spiralled rigid metal wire layer between the outer conductor of the coaxial transmission line and the outer jacket of the cable.

### SUMMARY OF THE INVENTION

One objective of the invention is to provide a robust, high flexible PIM test cable. A further objective of the invention is to provide PIM test cable having a stable low PIM performance even after several thousand cycles of repeated flexing.

A PIM test cable according to the invention comprises a cable assembly comprising a coaxial cable with an inner conductor and a shield (outer conductor) and a dielectric arranged between the inner conductor and the shield. Furthermore the cable assembly comprises a tubular outer jacket which encompasses the coaxial cable. The outer jacket protects the outer cable and prevents that external load is applied to the coaxial cable in a negative manner. In a preferred embodiment the outer jacket is foreseen to receive most of the external torsional load. Furthermore the outer jacket can be foreseen to limit the bending radius of coaxial cable. For optimized results the outer jacket is not rigidly attached or interconnected to the coaxial cable over its total length. Instead the outer jacket is attached to the coaxial cable in the region of both ends of the outer jacket. Along the length of the coaxial cable the outer jacket normally has a certain clearance with respect to the coaxial cable which at least locally allows relative movement between the outer jacket and the coaxial cable in a controlled manner which has no negative effect on the lifetime of the product.

Very good results can be achieved when the outer jacket is arranged at a certain distance from the coaxial cable, such that the outer jacket does not encompass the coaxial cable in a very tight manner and such that—if appropriate—locally a certain relative movement is allowed along the length of the cable. The distance between the outer jacket and the coaxial cable can e.g. be set by one or several spacers who are arranged between the coaxial cable and the outer jacket along the coaxial cable. During operation of cable assembly the distance between the outer jacket and the coaxial cable can vary locally along the length of the coaxial cable, e.g. depending on the presence of a spacer and/or the bending radius. The shield of the coaxial cable can be single or multi layered. Good results are achieved by a shield which comprises a layer of (double) braided wires, e.g. silver-plated cooper braid. The layer of braided wires can be tinned (tin-coated). If appropriate the shield can be encompassed by a cable sheath. Depending on the field of application the at least one spacer can be interconnected to the shield or, if present, to the cable sheath. Alternatively or in addition at least one spacer can be incorporated in the cable sheath, i.e. forming part thereof. This can be e.g. achieved by cable extrusion of melted plastic material forming the thin and the thick areas of the cable sheath. In a variation the at least one spacer can e.g. be made in a very simple manner from a shrink tube which is placed onto the coaxial cable. Alternatively or in addition the spacer can e.g. be made from a reversible deformable foam material. Good results are achieved when several spacers are arranged at defined distances along the length of the cable assembly. Smooth bending can be achieved when the spacers are arranged at a distance apart which corresponds about 20 to 120 times to the outer diameter of the coaxial cable. Furthermore the spacer can be made in the form of rings or a helical coil extending along the length of the coaxial cable.

Normally the outer jacket comprises an armour which protects the coaxial cable arranged on the inside against outer forces or over bending. Good results are achieved when the armour comprises a wire spiral preferably made out of steel or another appropriate material and which allows easy bending without negative transformation of the cross section. If appropriate the wire spiral can be made out of plastic. To prevent damage of the coaxial cable the wire spiral can be coated on the inside or embedded in a side wall of the outer jacket. In a variation the outer jacket may comprise a shower hose, or a braided armour. However, it should be kept in mind, that the shower hose is normally less bendable compared to the wire spiral and a braided armour tends not to have a stable cross section during bending. Normally the outer jacket comprises a protective sleeve which protects the inside of the cable assembly. If appropriate the armour can be embed in the protective sleeve. If appropriate at least one end of the outer jacket can be mechanically interconnected to a related connector by e.g. a handle made out of plastic material (e.g. cured sealing agent as described hereinafter). The mechanical connection transfers external load between the connector and the outer jacket thereby protecting the coaxial cable on the inside.

As mentioned above, the outer jacket is at least along certain segments not interconnected to the coaxial cable allowing relative movement of the coaxial cable with respect to the outer jacket. This may have a positive effect on the flexibility of the cable assembly. At the end of the coaxial cable a bushing can be mounted on the coaxial cable. This prevents negative kinking of the coaxial cable especially in the area where the coaxial cable exits the outer jacket and is not protected anymore by the outer jacket. Normally a connector is attached to a least one end of the coaxial cable. The at least one bushing can form part of a connector or comprise or be interconnected to a first interface suitable to receive a second interface of one or several connectors. Thereby different connectors can be attached to a pre-assembled cable assembly. In an embodiment the outer jacket is terminated by an end sleeve, whereby said end sleeve is foreseen to receive the at least one bushing. If appropriate a contact sleeve can be attached to the shield of the coaxial cable before the connector is interconnected. The contact sleeve supporting the electrical contact between the shield and the outer contact (housing) of the connector.

The design of the herein described cable assembly contributes to a long product life and consistent, repeatable measurements. Compared to test cables from the prior art this design is mechanically robust but very flexible compared to existing products. The product life is much higher than the current offerings.

### BRIEF DESCRIPTION OF SEVERAL VIEWS OF THE DRAWINGS

The herein described invention will be more fully understood from the detailed description given herein below and the accompanying drawings which should not be considered limiting to the invention described in the appended claims. The drawings are showing:

FIG. 1 is a cable assembly in a side view;

FIG. 2 is the cable assembly in a front view;

FIG. 3 is the cable assembly in a segmented section view along section line B-B of FIG. 2;

FIG. 4 is detail C of FIG. 3;

FIG. 5 is one end of a cable assembly in a perspective view;

FIG. 6 is a section view of the cable assembly according to FIG. 5.

### DETAILED DESCRIPTION OF THE INVENTION

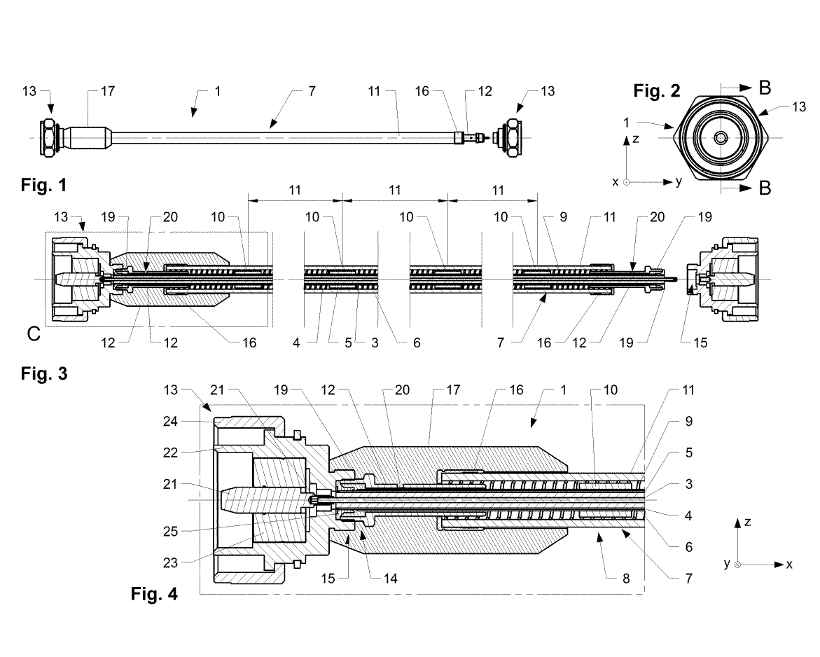

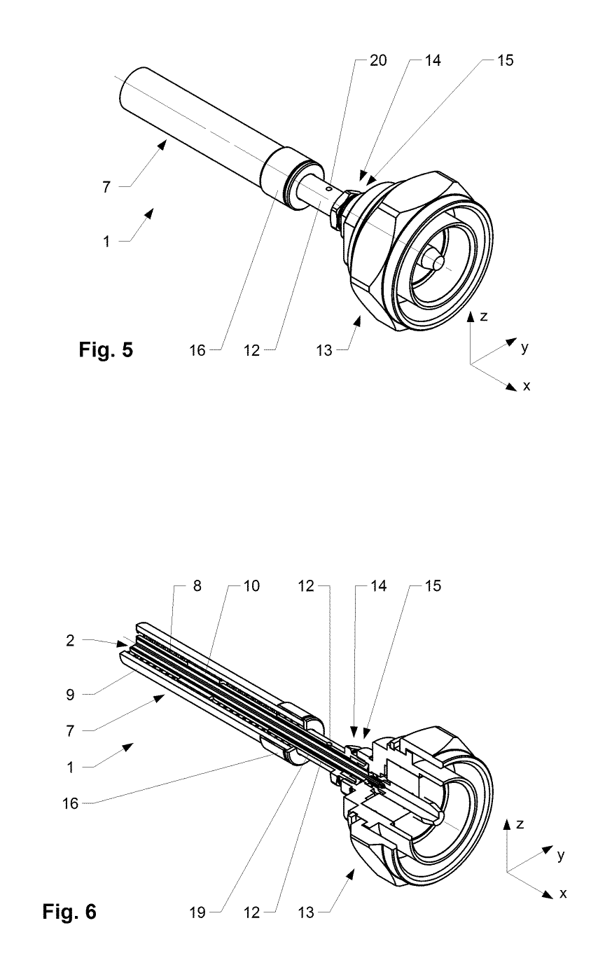

FIG. 1 shows a cable assembly 1 according to the invention in a side view. FIG. 2 shows the cable assembly in a front view and FIG. 3 shows a section view of the cable assembly along section line B-B as indicated in FIG. 2. FIG. 4 shows detail C as indicated in FIG. 3. FIG. 5 shows an end section of the cable assembly according to FIG. 1 and FIG. 6 shows the end section according FIG. 5 in a section view, such that the inside becomes partially visible.

As visible in FIG. 3 and FIG. 4 the cable assembly 1 comprises a coaxial cable 2 with an inner conductor 3, a shield (outer conductor) 4 and a dielectric 5 arranged between the inner conductor 3 and the shield 4. Furthermore the cable assembly 1 comprises a tubular outer jacket 7 which encompasses the coaxial cable 2 at a certain radial distance. Good results are achieved when the inner diameter of the outer jacket 7 is about 1.1 to 2 times of the outer diameter of the coaxial cable 2.

At each the end of the coaxial cable 2 a bushing 12 is mounted. This provides local stiffening and prevents negative kinking of the coaxial cable 2 especially in the area where the coaxial cable exits the outer jacket 7 and is not protected anymore. In the shown variation the coaxial cable 2 is at either end terminated by a connector 13 which are here attached to the coaxial cable 2 by a first and a second (standardized) interface 14, 15. This offers the advantage that the same cable assembly can be equipped with different types of connectors 13 and can thereby easily be adapted to different fields of application. If appropriate the bushings 12 can form part of a connector. On either end the outer jacket 7 is terminated by an end sleeve 16. The end sleeves 16 comprise an opening 18 which acts as guiding means for the therein arranged bushing 12.

As best visible in FIG. 4, the inside between the bushing 12 and the coaxial cable 2 is filled with a sealing compound 19. The sealing compound 19 is filled in by an filling opening 20 which is arranged here lateral at the bushing 12 such that during filling in the sealing compound 19 the space is thoroughly filled. If appropriate at least at one end of the cable assembly 1 the bushing 12, the end sleeve 16, the outer jacket 7 and the connector 13 can be encompassed by a handle 17. The handle 17 mechanically interconnects the several elements and safely prevents unwanted relative movement of the involved parts. Furthermore it transfers external load between the outer jacket and the connector 13 during operation and helps to securely protect the inside of the cable assembly, especially the coaxial cable 2. In a preferred embodiment the handle 17 is made out the same material as the sealing compound 19. E.g. the end of the cable assembly is inserted into a mold (not shown in detail) and the sealing compound is injected filling the space between the bushing 12 and the coaxial cable 2 by the opening 20 as well as the handle 17. After curing of the material the cable assembly 1 is removed from the mold. The radial distance between the outer jacket 7 and the coaxial cable 2 is defined by several spacers 10 which are arranged at an even distance 11 between the coaxial cable 2 and the outer jacket 7 along the coaxial cable 2. The shield of the coaxial cable can be single or multi layered. Good results are achieved by a shield 4 which comprises a layer of braided wires, e.g. silver-plated cooper braid, which are then tin-coated. However, depending on the field of application other shield types are possible.

In the shown variation the coaxial cable 2 comprises a cable sheath 6 is encompasses the shield 4. The spacers 10 are arranged attached to the outside of the cable sheath 6 such that they can inside the outer jacket 7 in length direction along with the coaxial cable 2. Alternatively or in addition at least one spacer 10 can be incorporated in the cable sheath, i.e. forming part thereof. This can be e.g. achieved by cable extrusion of melted plastic material forming the thin and the thick areas of the cable sheath. If appropriate the cable sheath 6 can have a constant thickness over its length. In a very simple manner the spacers 10 can e.g. be made from shrink tube which is placed onto the outer sheet 6 of the coaxial cable 2 and fixed by shrinking. Alternatively or in addition the spacer can e.g. be made from a reversible deformable foam material. Good results are achieved when several spacers 10 are arranged at defined distances 11 along the length of the coaxial cable 2. Smooth bending can be achieved when the spacers 10 are arranged at a distance A apart which corresponds about 20 to 120 times to the outer diameter of the coaxial cable. In a variation the spacer 10 itself may comprise one or several helical coils which extend at least partially along the coaxial cable 2.

As best visible in FIG. 4 the outer jacket 7 comprises an armour 8 which protects the coaxial cable 2 arranged on the inside against outer forces or over bending. Good results are achieved when the armour comprises a wire spiral 8 preferably made out of steel or another appropriate material and which allows easy bending without negative transformation of the cross section. To prevent damage of the coaxial cable the wire spiral 9 can be coated on the inside or embedded in a side wall of the armour 8. The outer jacket 7 here further comprises a protective sleeve 9 which protects the inside of the cable assembly 1 and prevents over stretching. If appropriate the armour 8 can be embed in the protective sleeve 9.

In the shown embodiment the connector 13 comprises a here male inner conductor 21 which is held within a housing (outer conductor) 22 by an insulator 23. Both are press-fit within the housing 22. At the rear end the connector 13 comprises a standardized interface 15 which comprises a first thread which can be can be engaged with a corresponding second thread of a corresponding standardized interface attached to an end of the coaxial cable 2. On the outside the connector 13 comprising fixing means, here in the form of a locking nut 24. As the connector 13 is detachable from the coaxial cable 2 by the standardized interfaces 14, 15 is possible to equip the cable assembly 1 easily with different types of connectors 13 as indicated in FIG. 3 on the right hand side.

As best visible in FIG. 4 in the shown variation a first contact sleeve 25 as attached to the end of the shield 4 of the coaxial cable 2. The contact sleeve 25 provides electrical contact between the shield 4 and the connector 13 and is normally attached alter the bushing 12 is slid on the coaxial cable 2. In the area where the contact sleeve 25 is applied, the cable sheath 6 is removed. Alternatively or in addition a second contact sleeve 26 can be foreseen. In the shown variation a second contact sleeve 26 is attached to the inner conductor 3. The second contact sleeve 26 provides electrical contact between the inner conductor 3 and the inner conductor 21 of the connector 13. This is advantages especially when the inner conductor 3 is a braided inner conductor.

Rather, the words used in the specification are words of description rather than limitation, and it is understood that various changes may be made without departing from the Spirit and scope of the invention.

1. A cable assembly (1) comprising:
a. a coaxial cable (2) with an inner conductor (3) and a shield (4) and a dielectric (5) arranged between the inner conductor (3) and the shield (4);
b. an outer jacket (7) which encompasses the coaxial cable (2) at a certain distance; wherein
c. at least one spacer (10) is arranged between the coaxial cable (2) and the outer jacket (7) such that the outer jacket (7) and the coaxial cable (2) are spaced a distance apart.

2. The cable assembly (1) according to claim 1, wherein the shield (4) comprises a layer of braided wires.

3. The cable assembly (1) according to claim 2, wherein layer of braided wires are tin-coated.

4. The cable assembly (1) according to claim 1, wherein the shield (4) is encompassed by a cable sheath (6).

5. The cable assembly (1) according to claim 1, wherein the at least one spacer (10) is attached to the cable sheath (6) of forms part thereof.

6. The cable assembly (1) according to claim 1, wherein spacers (10) are arranged at a distance (A) with respect to each other along the coaxial cable (2).

7. The cable assembly (1) according to claim 1, wherein the at least one spacer (10) is made from a shrink tube.

8. The cable assembly (1) according to claim 1, wherein the outer jacket (7) comprises an armour (8).

9. The cable assembly (1) according to claim 6, wherein the armour (8) comprises a wire spiral (9)

10. The cable assembly (1) according to claim 1, wherein the outer jacket (7) comprises a protective sleeve (9).

11. The cable assembly (1) according to claim 1, wherein the outer jacket (7) is movable along the length of the coaxial cable (2) with respect to the coaxial cable (2).

12. The cable assembly (1) according to claim 1, wherein a connector (13) is attached to a least one end of the coaxial cable (2).

13. The cable assembly (1) according to claim 1, wherein at least one bushing (12) is mounted on the coaxial cable (2).

14. The cable assembly (1) according to claim 13, wherein the at least one bushing (12) is mounted on the coaxial cable (2) in an area where the coaxial cable (2) exits the outer jacket (7).

15. The cable assembly (1) according to claim 13, wherein the at least one bushing (2) forms part of a connector (13).

16. The cable assembly (1) according to claim 13, wherein the at least one bushing (12) comprises or is interconnected to a first interface (14) suitable to receive a second interface (15) of one or several connectors (13).

17. The cable assembly (1) according to claim 12, wherein a first contact sleeve (25) is attached to the shield (4) of the coaxial cable (2) contributing to the electrical contact between the shield (4) and the outer conductor (22) of the connector (13).

18. The cable assembly (1) according to claim 1, wherein the outer jacket (7) is terminated by an end sleeve (16).

19. The cable assembly (1) according to claim 18, wherein the end sleeve (16) is suitable to receive the at least one bushing (12).

20. The cable assembly (1) according to claim 12, wherein at least at one end of the cable assembly (1) a handle (17) mechanically interconnects the outer jacket (7) and the related connector (13).

21. A PIM test cable comprising a cable assembly according to claim 1.
